(19) United States
(12) Patent Application Publication
(10) Pub. No.: US 2003/0222674 A1
(43) Pub. Date: Dec. 4, 2003

(54) Electronic circuit device and electronic device package

(75) Inventor: Shogo Hachiya, Ome-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/405,609

(22) Filed: Apr. 3, 2003

(30) Foreign Application Priority Data
May 31, 2002 (JP) 2002-160684

(51) Int. Cl. H03K 19/003

(52) U.S. Cl. 326/30

(57) ABSTRACT

In place of an arrangement that terminates a signal input circuit of a signal input buffer on a line of a transmission line part including a circuit board, cables, and the like, a signal output buffer arranged in an output-side electronic device part is directly circuit-connected to a signal input buffer arranged in an input-side electronic device part via a line of a transmission line part including a circuit board, cables, and the like without being terminated. Furthermore, the circuit is terminated by a terminating resistor near the input-side electronic device part via a terminating circuit line extending from that circuit connection part.

### CROSS-REFERENCE TO RELATED APPLICATIONS

This application is based upon and claims the benefit of priority from the prior Japanese Patent Application No. 2002-160684, filed May 31, 2002.

### BACKGROUND OF THE INVENTION

1. Field of the Invention

The present invention relates to an electronic circuit device and electronic device package, which are suitably applied to an electronic apparatus such as a computer system or the like, which requires a terminating circuit for preventing reflected noise, and, for example, handles a high-speed signal with a high clock frequency.

2. Description of the Related Art

In an electronic apparatus that handles a high-frequency signal, for example, in an electronic device such as a computer system that uses high-speed clocks with a high frequency, when a high-frequency transmission line input to an electronic device is terminated, it is recommended to insert a terminating component near pins (connection terminal) of the electronic device, so as to effectively prevent reflected noise.

A conventional terminating circuit has a signal output buffer which is arranged in an electronic device part on the signal output side, an input buffer which is arranged in an electronics part on the signal input side, a transmission line provided between the output buffer and the input buffer and a line in an electronic device part on the signal input side.

The signal output buffer supplies a high-speed clock or a high-frequency signal such as a digital signal that follows this high-speed clock to a signal input buffer via the transmission line such as a circuit pattern of a circuit board. On this circuit, a terminating resistor is connected on the line which is close to the signal input buffer as much as possible, so as to prevent reflected noise.

However, in recent years, in order to attain higher-speed processes in an electronic apparatus such as a computer system or the like, the frequency of a clock signal or the like is raised rapidly to the level at which the line, connection terminal, bonding wires, and the like in the electronic device part influence the transmission characteristics of the signal transmission line.

To solve this problem, a method of embedding a damping resistor in a semiconductor package, which is described in Jpn. Pat. Appln. KOKAI Publication No. 2-3260, adopts an arrangement in which a damping resistor is embedded in a semiconductor package. However, this method leads to an increase in package cost, and the like since it has poor degree of freedom in design with respect to a change in resistance constant, and uses a special package.

As described above, the conventional terminating circuit technique cannot fully make use of a reflected noise prevention function of the terminating circuit with respect to the current signal transmission of the high-speed operation frequency. Also, it becomes harder to insert a terminating resistor at an ideal position due to an increase in packaging density on the circuit board. Furthermore, the method of embedding a damping resistor in a semiconductor package may lead to an increase in packaging cost and the like, since it has poor degree of freedom in design with respect to a change in resistance constant, and uses a special package.

### BRIEF SUMMARY OF THE INVENTION

An embodiment of this present invention provides an electronic circuit device and electronic device package, which can fully make use of a reflected noise prevention function of a terminating circuit with respect to the current signal transmission of the high-speed operation frequency.

In order to achieve the above embodiment, according to the present invention, there is provided an electronic circuit device comprising a first circuit configured to output a signal, a second circuit having a terminal which configured to input the signal from the first circuit and a signal line which configured to transmit the signal from the terminal to a buffer provided in the second circuit, a terminating line, connected to the signal line, extended from the second circuit and a terminating resistor which is connected to the terminating line extended from the second circuit.

Additional embodiments and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a circuit diagram showing the arrangement of a signal transmission circuit including a terminating circuit according to the first embodiment of the present invention;

FIGS. 2A to 2C show a first practical example of the circuit arrangement in the first embodiment;

FIGS. 3A to 3C show a second practical example of the circuit arrangement in the first embodiment; and

FIG. 4 is a circuit diagram showing the arrangement of a signal transmission circuit including a terminating circuit according to the second embodiment of the present invention.

### DETAILED DESCRIPTION OF THE INVENTION

Preferred embodiments of the present invention will be described hereinafter with reference to the accompanying drawings.

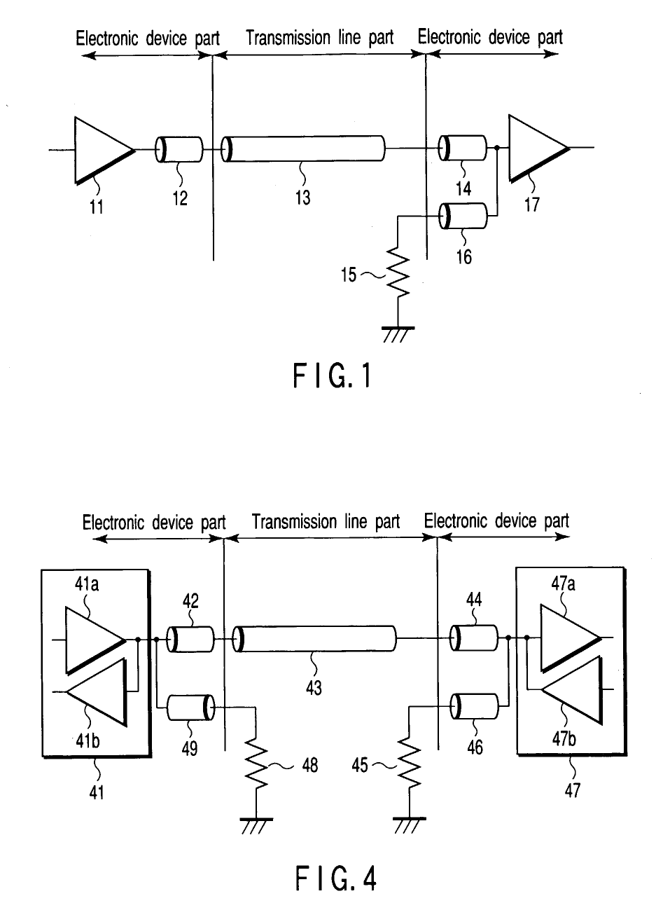

FIG. 1 is a circuit diagram showing the arrangement of a signal transmission circuit including a terminating circuit according to the first embodiment of the present invention. FIG. 1 illustrates circuit building components of respective parts of a high-frequency signal transmission circuit in which a high-frequency signal from a signal output buffer 11 arranged in a signal output side electronic device part is transmitted to a signal input buffer arranged in an input side electronic device part via a transmission line part including a circuit board, cables, and the like.

The circuit arrangement shown in FIG. 1 includes, as circuit components, a line 12 in the output-side electronic device part, a line 13 of the transmission line part including the circuit board, cables, and the like, a line 14 in the input-side electronic device part, between the signal output buffer 11 arranged in the electronic device part on the signal output side, and a signal input buffer 17 arranged in the electronic device part on the signal input side. Also, the arrangement includes, as circuit components, an electrical terminal that connects the output-side electronic device part and transmission line part (between the lines 12 and 13), an electrical terminal that connects the transmission line part and input-side electronic device part (between the lines 13 and 14), and the like.

In the present invention, a line (terminating circuit line) 16 dedicated to a terminating circuit extends outside a package of the input-side electronic device part (to the transmission line part) to have as a start point a connection circuit part between the line 14 in the input-side electronic device part and the signal input buffer 17. That is, the terminating circuit line 16 has one end connected to the connection circuit part between the line 14 in the input-side electronic device part and signal input buffer 17, and the other end extended outside the package of the input-side electronic device part. A terminating resistor 15 is connected to the terminating circuit line 16 which extends from the input-side electronic device part. In this case, the terminating resistor 15 is desirably inserted at a position close to the signal input buffer 17 on the circuit board, as much as possible.

In the circuit arrangement shown in FIG. 1, a signal input circuit of the signal input buffer 17 is not terminated on the line 13 of the transmission line part including the circuit board, cables, and the like. The signal output buffer 11 arranged in the output-side electronic device part is directly circuit-connected to the signal input buffer 17 arranged in the input-side electronic device part via the line 13 of the transmission line part including the circuit board, cables, and the like without being terminated. Furthermore, the signal output buffer 11 is terminated by the terminating resistor 15 near the input-side electronic device part via the terminating circuit line 16 extending from that circuit connection part.

That is, in the circuit arrangement shown in FIG. 1, a high-frequency signal output from the signal output buffer 11 in the output-side electronic device part is transmitted to the signal input buffer 17 via the line 12 in the output-side electronic device 12, the line 13 of the transmission line part including the circuit board, cables, and the like, and the line 14 in the input-side electronic device part. The high-frequency signal is then terminated by the terminating resistor 15 via another line (terminating circuit line) 16 in that input-side electronic device part at its transmission end (circuit connection end between the line 14 and signal input buffer 17).

Upon comparing the circuit arrangement according to the embodiment of the present invention shown in FIG. 1 with the conventional circuit arrangement, the impedance of the input-side device part, which is viewed from the transmission line part, is very high between the transmission line part that includes transmission line (line), terminating resistor, and the like, and the input-side electronic device part that includes the line, signal input buffer, and the like (the input impedance of an ideal MOS-FET is infinite) in the conventional circuit arrangement. Hence, the conventional circuit arrangement readily generates reflected noise due to impedance mismatch.

By contrast, in the circuit arrangement according to the embodiment of the present invention shown in FIG. 1, the impedance of the input-side device part, which is viewed from the transmission line part, is very low between the transmission line part that includes the line 13, terminating resistor 15, and the like, and the input-side electronic device part that includes the line 14, signal input buffer 17, and the like, since the circuit is terminated at the transmission end of the line 14 to the signal input buffer 17 (circuit connection end) by the other line (terminating circuit line) 16 in the input-side electronic device. Therefore, the waveform quality of a signal with a high frequency such as high-speed clocks and the like can be improved. Such effects can be easily demonstrated by transmission line simulation and the like.

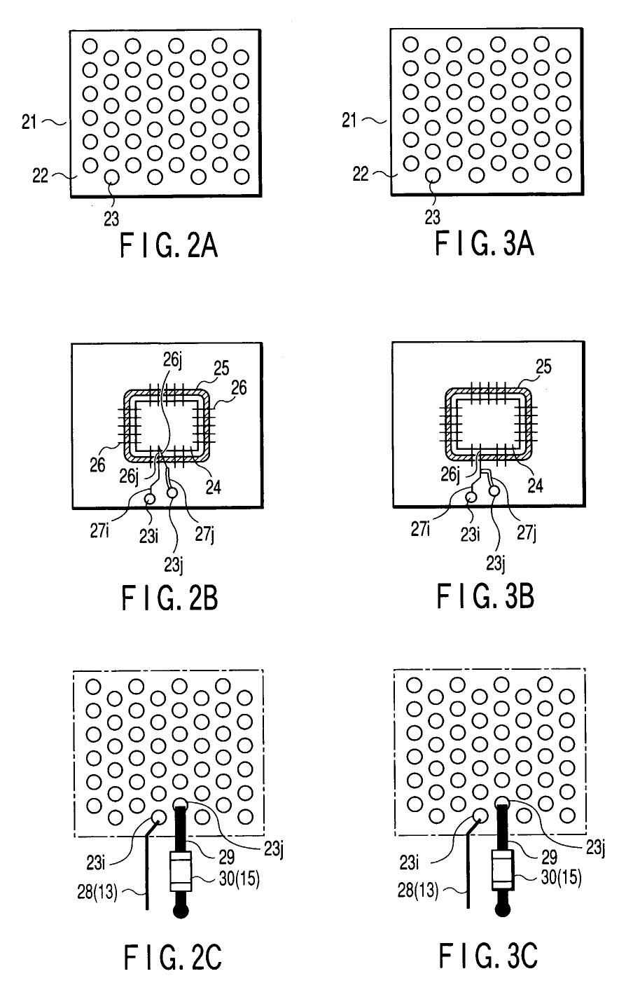

FIGS. 2A to 3C show practical examples of the circuit arrangement of the present invention, which adopt the aforementioned circuit arrangement of the present invention. FIGS. 2A to 2C show the first practical example of the circuit arrangement, and FIGS. 3A to 3C show the second practical example of the circuit arrangement. In this case, a BGA package is exemplified as an electronic device package, and practical examples of the circuit arrangement in which the present invention is applied to the mounted circuit part of the BGA package are shown in FIGS. 2A to 2C, and FIGS. 3A to 3C. Note that the first practical example of the circuit arrangement shown in FIGS. 2A to 2C, and the second example of the circuit arrangement shown in FIGS. 3A to 3C have identical circuit arrangements, except for FIGS. 2B and 3B.

FIG. 2A shows the rear surface arrangement of a BGA package 21, FIG. 2B shows the internal structure of the BGA package 21, and FIG. 2C shows an example of a printed circuit board layout that mounts the BGA package 21.

As shown in FIG. 2A, BGA solder balls 23, which serve as electrical connection terminals, are arranged in a matrix, on a rear surface portion 22 of the BGA package 21. The BGA package 21 includes a semiconductor chip 24 that handles a high-frequency signal, a ground ring 25, bonding wires 26 that circuit-connect the semiconductor chip 24 in the package, and the like, as shown in FIG. 2B.

Furthermore, in this embodiment, in addition to a signal transmission wire 27i which connects between a BGA solder ball 23i that serves as a high-frequency signal input terminal (signal input pad) of the BGA package 21, and a bonding wire 26i, connected to the BGA solder ball 23i, of the semiconductor chip 24 in the BGA package 21, a terminating wire 27j that forms a terminating circuit is connected to the high-frequency signal input terminal of the semiconductor chip 24 via another bonding wire 26j. More specifically, in addition to a signal input circuit formed by the BGA solder ball 23i, signal transmission wire 27i, bonding wire 26i, and the like, a terminating circuit formed by the binding wire 26j, terminating wire 27j, BGA solder ball 23j, and the like is provided. The BGA solder ball 23i corresponds to an electrical terminal, which serves as a connection node between the line 13 of the transmission line part including the circuit board, cables, and the like, and the line 14 in the input-side electronic device part shown in FIG. 1. Also, the wire 27i corresponds to the line 14 in the input-side electronic device part shown in FIG. 1.

In this terminating circuit, the high-frequency signal input terminal (signal input pad) of the semiconductor chip 24 is connected to the BGA solder ball 23j via the bonding wire 26j and terminating wire 27j. Note that the terminating wire 27j corresponds to the other line 16 in the input-side electronic device part, and the BGA solder ball 23j corresponds to a terminal which serves as a connection node between the other line 16 in the input-side electronic device part shown in FIG. 1, and the terminating resistor 15.

As shown in FIG. 2C, a wire 28 of the transmission line part including the circuit board, cables, and the like is connected to the BGA solder ball 23i which serves as the high-frequency signal input terminal of the BGA package 21, on the printed circuit board surface. Also, to the BGA solder ball 23j, a terminating resistor 30 is connected to the ground near the BGA package 21 via a wiring pattern 29. Note that the wire 28 of the transmission line part corresponds to the line 13 of the transmission line part including the circuit board, cables, and the like, shown in FIG. 1, and the terminating resistor 30 corresponds to the terminating resistor 15.

In the circuit arrangement shown in FIGS. 2A to 2C, the high-frequency signal input terminal of the semiconductor chip 24 is terminated by the terminating resistor 30 (corresponding to the terminating resistor 15 in FIG. 1) via the bonding wire 26j, terminating wire 27j (corresponding to the other line 16 in the input-side electronic device part in FIG. 1), BGA solder ball 23j, and the like. Hence, the impedance of the input-side electronic device part (the high-frequency signal input terminal of the semiconductor chip 24), when viewed from the transmission line part (wire 28), is very low. Therefore, the waveform quality of a signal with a high frequency such as high-speed clocks and the like can be improved.

In the second practical example of the circuit arrangement shown in FIGS. 3A to 3C, the BGA package 21 includes a semiconductor chip 24 that handles a high-frequency signal, a ground ring 25, bonding wires 26 that circuit-connect the semiconductor chip 24 in the package, and the like, as shown in FIG. 3B. Furthermore, in addition to a signal transmission wire 27i which connects between a BGA solder ball 23i that serves as a high-frequency signal input terminal of the BGA package 21, and a bonding wire 26i, connected to the BGA solder ball 23i, of the semiconductor chip 24, a terminating wire 27j and terminating BGA solder ball 23j that form a terminating circuit are connected to the high-frequency signal input terminal of the semiconductor chip 24. One end of the terminating wire 27j is connected to a circuit part that connects the bonding wire 26i and the signal transmission wire 27i, and the other end thereof is connected to the terminating BGA solder ball 23j.

In this terminating circuit, the high-frequency signal input terminal (signal input pad) of the semiconductor chip 24 is connected to the terminating BGA solder ball 23j via the bonding wire 26i and terminating wire 27j. Note that the terminating wire 27j corresponds to the other line 16 in the input-side electronic device part shown in FIG. 1. Also, the terminating BGA solder ball 23j corresponds to a terminal that serves as a connection node between the other line 16 in the input-side electronic device part, and the terminating resistor 15.

In the circuit arrangement shown in FIGS. 3A to 3C, the high-frequency signal input terminal of the semiconductor chip 24 is terminated by a terminating resistor 30 (corresponding to the terminating resistor 15 in FIG. 1) via the bonding wire 26i, the terminating wire 27j (corresponding to the other line 16 in the input-side electronic device part in FIG. 1), the terminating BGA solder ball 23j, a wiring pattern 29, and the like. Hence, the impedance of the input-side electronic device part (the high-frequency signal input terminal of the semiconductor chip 24), when viewed from the transmission line part (wire 28), is very low. Therefore, the waveform quality of a signal with a high frequency such as high-speed clocks and the like can be improved, as in the embodiment shown in FIGS. 2A to 2C.

FIG. 4 shows the arrangement of a signal transmission circuit including a terminating circuit according to the second embodiment of the present invention, in which the terminating circuit technique of the present invention is applied to an electronic device for two-way communications. In this example, the present invention is applied to the circuit arrangement in which an electronic device part (A) that comprises an input/output buffer 41 and an electronic device part (B) which comprises an input/output buffer 47 are connected via a line 43 of a transmission line part which includes a circuit pattern of a circuit board, cables, and the like.

In the circuit arrangement shown in FIG. 4, a signal output from a signal output buffer 41a of the input/output buffer 41 is input to a signal input buffer 47a of the input/output buffer 47 via a line 42 in the electronic device part (A), the line 43 of the transmission line part, and a line 44 in the electronic device part (B). Also, a signal output from a signal output buffer 47b of the input/output buffer 47 is input to a signal input buffer 41b of the input/output buffer 41 via the line 44 in the electronic device part (B), the line 43 of the transmission line part, and the line 42 in the electronic device part (A).

Furthermore, in the circuit arrangement shown in FIG. 4, a line (terminating circuit line) 46 dedicated to a terminating circuit extends outside the package of the electronic device part (B) (to the transmission line part) to have as a start point a connection circuit part between the line 44 in the electronic device part (B) and the signal input buffer 47a. A terminating resistor 45 is connected to that terminating circuit line 46. Also, a line (terminating circuit line) 49 dedicated to a terminating circuit extends outside the package of the electronic device part (A) (to the transmission line part) to have as a start point a connection circuit part between the line 42 in the electronic device part (A) and the signal input buffer 41b. A terminating resistor 48 is connected to that terminating circuit line 49.

In the circuit arrangement shown in FIG. 4, the transmission end (circuit connection end) of the line 44 to the input/output buffer 47 is terminated by the terminating resistor 45 near the input/output buffer 47 arranged in the electronic device part (B) via the other line (terminating circuit line) 46 in the electronic device part (B) between the transmission line part that includes the line 43, terminating resistor 45, and the like, and the electronic device part (B) including the line 44, input/output buffer 47, and the like. Also, the transmission end (circuit connection end) of the line 42 to the input/output buffer 41 is terminated by the terminating resistor 48 near the input/output buffer 41 arranged in the electronic device part (A) via the other line (terminating circuit line) 49 in the electronic device part (A) between the transmission line part that includes the line 43, terminating resistor 48, and the like, and the electronic device part (A) including the line 42, input/output buffer 41, and the like.

In such circuit arrangement as well, the impedance on the signal input side is very low, as in the embodiment shown in FIG. 1. Therefore, the waveform quality of a signal with a high frequency such as high-speed clocks and the like can be improved.

In the above embodiments, the BGA package has been exemplified as an electronic device, but the present invention can be applied to all other semiconductor devices. For example, in an electronic circuit that uses a semiconductor device having a lead frame, a lead frame, inner lead, or outer lead dedicated to a terminating circuit may be connected to that semiconductor device to form the terminating circuit using such lead.

Furthermore, the terminating resistor may be provided in the semiconductor package.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic circuit device comprising:
a first circuit configured to output a signal;
a second circuit having a terminal which configured to input the signal from the first circuit and a signal line which configured to transmit the signal from the terminal to a buffer provided in the second circuit;
a terminating line, connected to the signal line, extended from the second circuit; and
a terminating resistor which is connected to the terminating line extended from the second circuit.

2. A device according to claim 1, wherein the terminating line is connected to a pad of the semiconductor circuit element.

3. A device according to claim 1, wherein the terminating line is connected to a pad used to input the high-frequency signal to the semiconductor circuit element.

4. A device according to claim 1, wherein the terminating line includes a bonding wire.

5. A device according to claim 1, wherein the terminating line includes a lead frame.

6. A device according to claim 2, wherein the pad is a connection terminal between the terminating line and the terminating resistor.

7. An electronic device package for supplying a signal to a semiconductor circuit element in an electronic device, comprising:
a signal line which supplies the signal to the semiconductor circuit element in the electronic device;
a terminating line which is connected to the signal line in the electronic device, and extends from the electronic device; and
a terminating resistor which is connected to the terminating line extending from the electronic device.

8. A package according to claim 7, wherein the terminating line is connected to a pad of the semiconductor circuit element.

9. A package according to claim 7, wherein the terminating line is connected to a pad used to input the high-frequency signal to the semiconductor circuit element.

10. A package according to claim 7, wherein the terminating line includes a bonding wire.

11. A package according to claim 7, wherein the terminating line includes a lead frame.

12. A package according to claim 8, wherein the pad is a connection terminal between the terminating line and the terminating resistor.

13. An electronic apparatus comprising:
a first circuit configured to output a signal;
a second circuit having a first terminal which configured to input the signal from the first circuit and a signal line which configured to transmit the signal from the terminal to a buffer provided in the second circuit;
a terminating line connected to the signal line;
a terminating resistor which is connected to the terminating line, extending from the second circuit; and
a second terminal which is connected to the terminating resistor, and provided to the second circuit to extend from the second circuit.
